(19) United States
(12) Patent Application Publication
(10) Pub. No.: US 2007/0281485 A1
(43) Pub. Date: Dec. 6, 2007

(54) Method of and apparatus for semiconductor device

(75) Inventor: Koji Torii, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/806,395

(22) Filed: May 31, 2007

(30) Foreign Application Priority Data
Jun. 2, 2006 (JP) 2006-154741

(51) Int. Cl. H01L 21/461; H01L 21/306

(52) U.S. Cl. 438/692; 438/693; 156/345.12; 156/345.13

(57) ABSTRACT

A semiconductor device fabrication method by which a semiconductor wafer is polished by pressing the semiconductor wafer against a polishing pad includes: an optimum condition calculation step for finding polishing conditions based on the hardness of the polishing pad; and a step of polishing the semiconductor wafer according to the polishing conditions that have been found.

### BACKGROUND OF THE INVENTION

1. Field of the Invention

The present invention relates to a fabrication method and fabrication apparatus of a semiconductor device.

2. Description of the Related Art

The degree of flatness of a semiconductor wafer surface which is sought in the fabrication process of a semiconductor device becomes increasing critical with the miniaturization of patterns to be formed on the wafer. The polishing method known as CMP (Chemical Mechanical Polishing) came into typical use when the processing rule of a semiconductor device becomes smaller than 0.35 μm. The CMP process is useful in eliminating differences in level in a semiconductor wafer surface.

In CMP, polishing is carried out by pressing the semiconductor wafer against a polishing pad. At this time, non-uniformity may occur in the pressure against the polishing pad at the edges of the semiconductor wafer. A uniform amount of polishing is difficult to achieve in the areas around the edges of a semiconductor wafer in which pressure has become non-uniform. In other words, the non-uniformity of pressure at the edges of a semiconductor wafer deteriorates within wafer uniformity of the polishing amount.

Advances have been made in producing larger semiconductor wafers in recent years, resulting in wafers with a diameter of 300 mm (i.e., 12 inches). When the surface of a semiconductor wafer of a large diameter is polished, the above-described non-uniformity of pressure at the edges of the semiconductor wafer becomes more pronounced, calling for an even greater improvement of the within wafer uniformity.

In relation to this problem, WO2003/000462 discloses a technique for increasing productivity in CMP by achieving superior polishing uniformity, as well as for discovering problem points in the fabrication processing of a semiconductor device, and reducing the amount of time required for dealing with these problems. JP-A-2000-117626 discloses a technology for accurately detecting the amount of polishing to achieve uniform polishing over the entire wafer surface. JP-A-2002-66908 discloses the use of a polishing pad containing polyvinyl alcohol insoluble in water to enable both a reduction of the adhesion of dust to the surface of a polished article to decrease scratches and further, to realize a flattening characteristic. JP-A-2004-186493 discloses setting the dressing pressure to 29 g/cm² (2.84 kPa) in a CMP process to reduce surface differences in level.

However, there is no disclosure in any of the above-described documents regarding uniform polishing of the surface of the semiconductor wafer by making the pressure uniform at the edges of a semiconductor wafer. Further, in an actual fabrication line of a semiconductor device, a plurality of semiconductor wafers are polished in order, and the uniformity of polishing diminishes with successive polishing processes. None of the above-described documents provides a solution for this degradation of uniformity accompanying increase in the number of wafers polished.

### SUMMARY OF THE INVENTION

It is an object of the present invention to provide a semiconductor device fabrication method and fabrication device which enable the uniform polishing of the surface of a semiconductor wafer.

It is another object of the present invention to provide a semiconductor device fabrication method and fabrication device which enable the uniform application of pressure to the edges of a semiconductor wafer when polishing the semiconductor wafer.

It is yet another object of the present invention to provide a semiconductor device fabrication method and fabrication device which enable uniform polishing of a surface despite usage in a plurality of polishing processes.

The object of the present invention is achieved by a semiconductor device fabrication method for polishing a semiconductor wafer by pressing a semiconductor wafer against a polishing pad, the method including: an optimum condition calculation step for finding polishing conditions based on the hardness of the polishing pad; and a step of polishing a semiconductor wafer according to the polishing conditions which have been found.

The inventors found that the polishing conditions which enable uniform polishing of the surface of a semiconductor wafer depend on the hardness of the polishing pad. The surface of a semiconductor wafer can always be uniformly polished by finding polishing conditions based on the hardness of the polishing pad.

In the fabrication method of the present invention, a step for measuring the hardness of the polishing pad is preferably provided, and in the optimum condition calculation step, the polishing conditions are preferably found based on the hardness of the polishing pad which has been measured. Alternatively, in the fabrication method of the present invention, the optimum condition calculation step may include a step for estimating the hardness of the polishing pad based on time information which indicates the time interval over which the polishing pad has been exposed to conditions causing exhaustion of the polishing pad, and the polishing conditions then found based on the estimated hardness of the polishing pad.

The hardness of the polishing pad changes over time due to the conditions to which the polishing pad is exposed. According to the present invention, hardness is estimated based on the time interval over which the polishing pad is exposed to conditions causing exhaustion, and the hardness of the polishing pad therefore need not be continuously measured.

In the fabrication method of the present invention, the time information may preferably include polishing time, which indicates the time interval over which the polishing pad was used in the polishing process. Changes in the hardness of the polishing pad largely depend on the polishing time. By taking the polishing time as a basis, the hardness of the polishing pad can be estimated accurately.

Alternatively in the above-described semiconductor device fabrication method of the present invention, the time information may preferably include wet idle time which indicates the time interval over which the polishing pad has been placed in wet idle. The hardness of the polishing pad may sometimes changes with the pad placed in wet idle. The hardness of the polishing pad can be accurately estimated by taking the wet idle time as a basis.

Alternatively in the fabrication method of the present invention, the polishing conditions may preferably include: the retainer ring pressure at which a retainer ring that is arranged around the periphery of the semiconductor wafer during polishing and that guides the semiconductor wafer is pressed against the polishing pad. Controlling the retainer ring pressure enables control over the distribution of pressure at the edges of the semiconductor wafer. Optimizing the retainer ring pressure therefore enables uniform polishing of the semiconductor wafer surface.

Alternatively in the fabrication method of the present invention, the polishing conditions may preferably include the peripheral pressure applied to the outer periphery of the semiconductor wafer when the semiconductor wafer is pressed against the polishing pad. The distribution of pressure at the edges of the semiconductor wafer depends on the peripheral pressure. Optimizing the peripheral pressure condition therefore enables uniform polishing of the semiconductor wafer surface.

The object of the present invention is also achieved by a semiconductor device fabrication device for pressing a semiconductor wafer against a polishing pad to polish the semiconductor wafer, the fabrication device having: a polishing unit including a polishing pad for polishing a semiconductor wafer; and a control unit for finding polishing conditions based on the hardness of the polishing pad and controlling the operation of the polishing unit such that polishing is carried out under the polishing conditions which have been found.

The fabrication device of the present invention is preferably equipped with a hardness measurement unit for measuring the hardness of the polishing pad, and the control unit preferably finds the polishing conditions based on the measurement results of the hardness measurement unit. Alternatively, in the fabrication device of the present invention, the control unit may estimate the hardness of the polishing pad based on time information that indicates the time interval over which the polishing pad has been exposed to exhausting conditions, and when finding the polishing conditions, may find the polishing conditions based on the estimated hardness of the polishing pad.

The above and other objects, features, and advantages of the present invention will become apparent from the following description referring to the accompanying drawings which illustrate an example of a preferred embodiment of the present invention.

### BRIEF DESCRIPTION OF THE DRAWINGS

FIG. 1 is a view showing the configuration of a semiconductor device fabrication device;

FIG. 2 is a top view of a polishing pad;

FIG. 3 is a schematic view of the polishing unit;

FIG. 4 is a view showing the distribution of pressure applied to the edges of a semiconductor wafer; and

FIG. 5 is a view showing the configuration of a hardness meter;

FIG. 6 is a block diagram showing the configuration of the control unit;

FIG. 7 is a schematic view showing an example of data stored in the storage unit;

FIG. 8 is a graph showing an example of the correspondence relation between the amount of change in hardness and the optimum polishing conditions;

FIG. 9 is a flow chart of the fabrication method of a semiconductor device in the first embodiment;

FIG. 10 is an explanatory view of the effect of the first embodiment;

FIG. 11 is a schematic view showing an example of data stored in the storage unit;

FIG. 12 is a schematic view showing an example of data stored in the storage unit;

FIG. 13 is a graph showing an example of the correspondence relation between the polishing time and the optimum polishing conditions;

FIG. 14 is a flow chart showing the semiconductor device fabrication method in the second embodiment;

FIG. 15 is a schematic view showing an example of data stored in the storage unit; and

FIG. 16 is a graph showing the relation between hardness and the wet idle time.

### DETAILED DESCRIPTION OF THE PREFERRED EMBODIMENTS

### First Embodiment

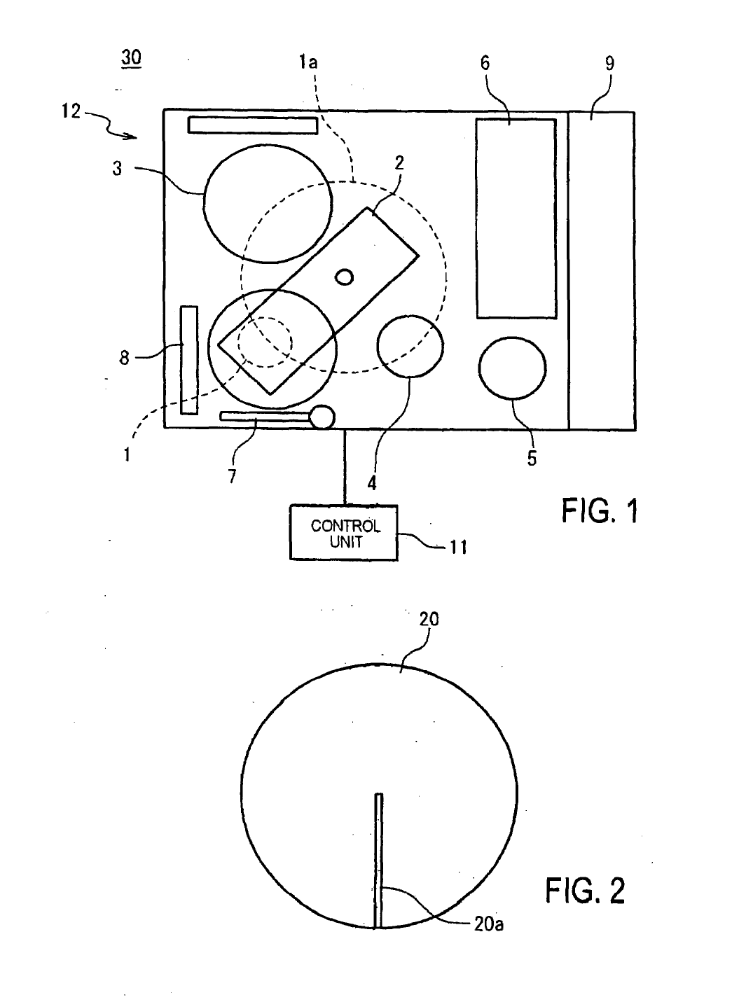

Semiconductor device fabrication device 30 of the first embodiment shown in FIG. 1 is equipped with: polishing unit 12 for carrying out polishing of a semiconductor wafer; hardness meter 7 for measuring the hardness of a polishing pad; and control unit 11 for controlling the operation of polishing unit 12 and hardness meter 7.

Polishing unit 12 includes: head 1, cross 2, platen 3, load/unload unit 4, robot 5, cleaning unit 6, dresser 8, and interface 9. The role of each component is described below.

Head 1 is for holding semiconductor wafer 19. Cross 2 is for supporting head 1, and applies a rotational motion to head 1 that describes head orbit 1a. Platen 3 is a part for affixing polishing pad 20. When polishing semiconductor wafer 19, platen 3 rotates, and polishing is carried out by pressing semiconductor wafer 19 supported on head 1 against polishing pad 20 which is affixed to platen 3. Load/unload unit 4 is a component for attaching and detaching semiconductor wafer 19 to and from head 1. Robot 5 is a component for conveying semiconductor wafer 19 into polishing unit 12 by way of interface 9. Robot 5 further moves semiconductor wafer 19 for which polishing has been completed to cleaning unit 6. When the process has been completed in cleaning unit 6, robot 5 conveys semiconductor wafer 19 to the outside by way of interface 9. Cleaning unit 6 is a component for cleaning semiconductor wafer 19 for which polishing has been completed. Dresser 8 is a component for adjusting the surface state of the polishing pad.

A component made of polyurethane can be offered as one example of polishing pad 20. Polishing pad 20 is consumed as the polishing process is carried out, and must therefore be exchanged as necessary. In addition, polishing pad 20 is in some cases processed with grooves and holes according to necessity. As will be explained hereinbelow, these grooves and holes have an influence on measurement when hardness is measured by means of hardness meter 7. Thus, a physical property measurement site 20a in which processing such as for holes or grooves is not carried out may be provided in an area of a portion of polishing pad 20, as shown in FIG. 2. To measure the hardness of physical property measurement site 20a, a datum point may be determined in advance at a prescribed location of platen 3, and a mechanism (not shown) may be provided for setting the angle of rotation of the platen by means of a pulse motor before the measurement of hardness to enable specification of the location of physical property measurement site 20a.

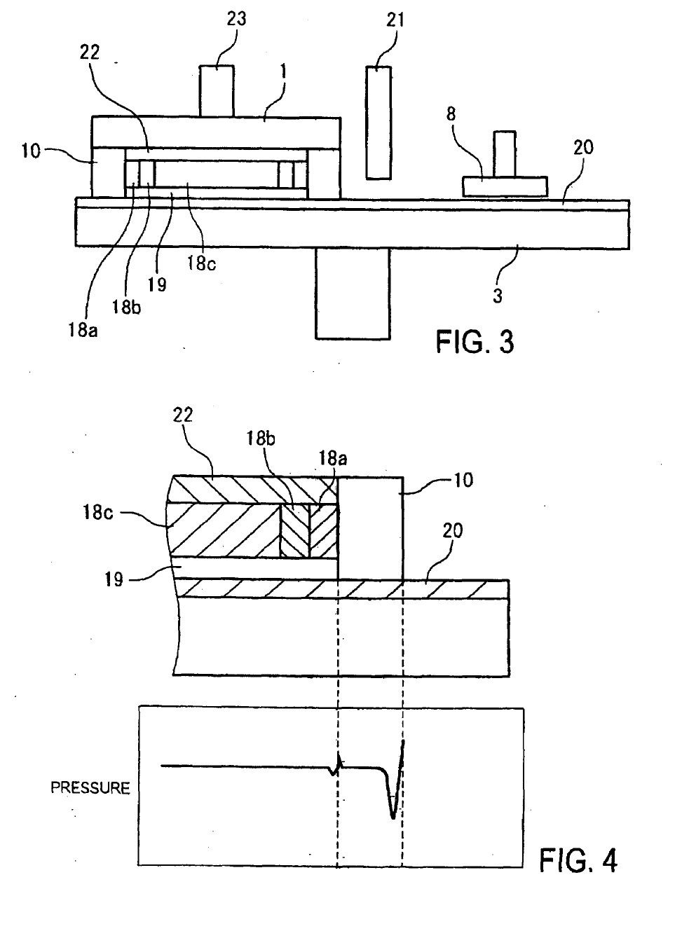

Explanation next regards the details of each component arranged on polishing pad 20 during polishing with reference to FIG. 3.

At the time of polishing, as previously described, head 1 holds semiconductor wafer 19 and presses semiconductor wafer 19 against polishing pad 20, this head 1 being supported by spindle 23. Although not shown in FIG. 3, spindle 23 is attached to cross 2 (see, FIG. 1)

Membrane support 22 is arranged in the center of the semiconductor wafer holding surface of head 1, that is, the surface of head 1 which holds the semiconductor wafer. Membrane support 22 holds three membranes 18a, 18b, and 18c, and the three membranes are arranged in the order 18a, 18b and 18c from the outer periphery. Semiconductor wafer 19 is held to head 1 by way of these membranes 18a, 18b, and 18c. During polishing, pressure is applied to semiconductor wafer 19 from membranes 18a, 18b, and 18c to press semiconductor wafer 19 against polishing pad 20. Membranes 18a, 18b and 18c are of a configuration which allows separate control of the pressure exerted by each against semiconductor wafer 19.

Retainer ring 10 is provided at the periphery of the semiconductor wafer holding surface of head 1. Retainer ring 10 is a component for guiding semiconductor wafer 19. The shape of the inside circumference of retainer ring 10 corresponds to the shape of semiconductor wafer 19 to be secured, and semiconductor wafer 19 is held within this retainer ring 10.

Retainer ring 10 is pressed against polishing pad 20 at a prescribed pressure during polishing. By being pressed against polishing pad 20, retainer ring 10 can serve the roles of not only guiding semiconductor wafer 19 which is the member that undergoes polishing, but also of making the pressure uniform at the edges of semiconductor wafer 19.

FIG. 4 shows the pressure acting upon semiconductor wafer 19 and retainer ring 10 during polishing. Pressure is nonuniform at the outer edges of retainer ring 10. This non-uniformity occurs because the polishing pad is prone to deformation at the edges, resulting in non-uniformity in the reaction force from the polishing pad toward retainer ring 10. This tendency for non-uniformity of pressure can be expected to occur at the edges of semiconductor wafer 19 when retainer ring 10 is not being pressed against the polishing pad. In other words, by pressing retainer ring 10 against polishing pad 20, the area in which pressure is not uniform can be shifted from the edges of semiconductor wafer 19 to the outer edges of retainer ring 10.

Referring again to FIG. 3, abrasive nozzle 21 is arranged above the center of polishing pad 20. During polishing, slurry is abrasive supplied to polishing pad from abrasive nozzle 21.

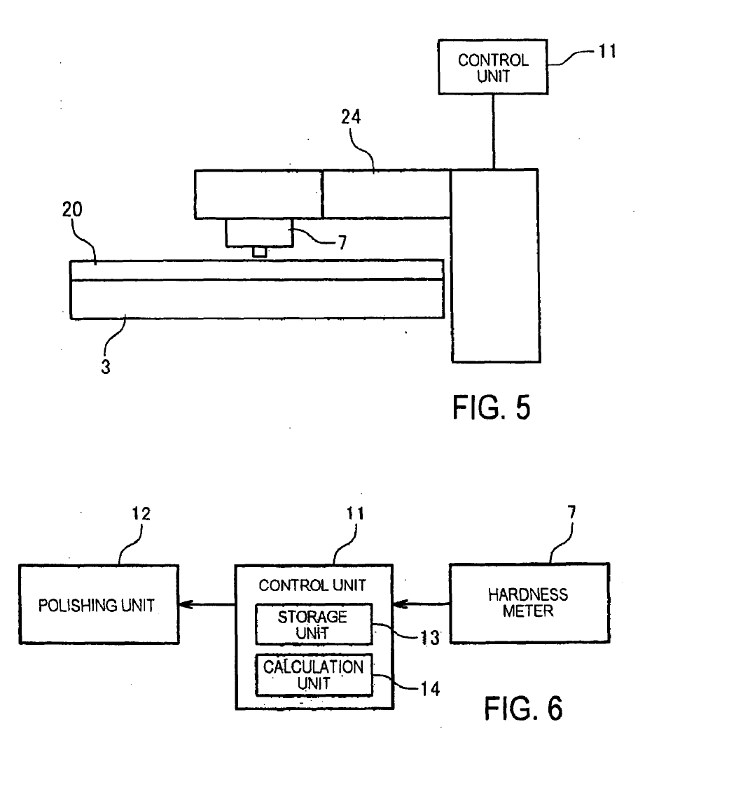

Explanation next regards hardness meter 7. FIG. 5 gives a schematic representation of the side surface of hardness meter 7. Hardness meter 7 is supported on arm 24. When hardness is to be measured, the tip of arm 24 to which hardness meter 7 is attached moves vertically to press hardness meter 7 against the surface of polishing pad 20 at a prescribed pressure, whereby hardness meter 7 measures the hardness of polishing pad 20. The measurement data of hardness meter 7 is communicated to control unit 11. Hardness meter 7 is thus a component for measuring the hardness of polishing pad 20 which is applied to platen 3. A Shore D hardness tester is shown as one example of hardness meter 7.

Explanation next regards control unit 11. FIG. 6 is a block diagram showing the configuration of control unit 11. Control unit 11 is connected to polishing unit 12 and hardness meter 7 and realizes the function of controlling the operations of these components. Control unit 11 is a computer equipped with a CPU (central processing unit), RAM (random access memory) and the like, and realizes these functions through the cooperation of hardware and an installed software program. Control unit 11 calculates the optimum polishing conditions while carrying out polishing based on the hardness of polishing pad 10 that is reported from hardness meter 7. Control unit 11 then controls the operations of polishing unit 12 such that polishing is carried out by the calculated optimum polishing conditions. The configuration and function of control unit 11 will be described below.

Control unit 11 includes storage unit 13 and calculation unit 14. The functionality of calculation unit 14 can be realized by software installed in control unit 11. Calculation unit 14 realizes the function of, based on the hardness data which were measured in hardness meter 7, referring to storage unit 13 to find the optimum polishing conditions. The correspondence relation between the hardness of polishing pad 20 and the polishing conditions for uniformly polishing a surface is stored in advance in storage unit 13. A hard disk drive (HDD) is shown as one example of storage unit 13. Another data relating to polishing conditions when carrying out polishing are also stored as necessary in storage unit 13.

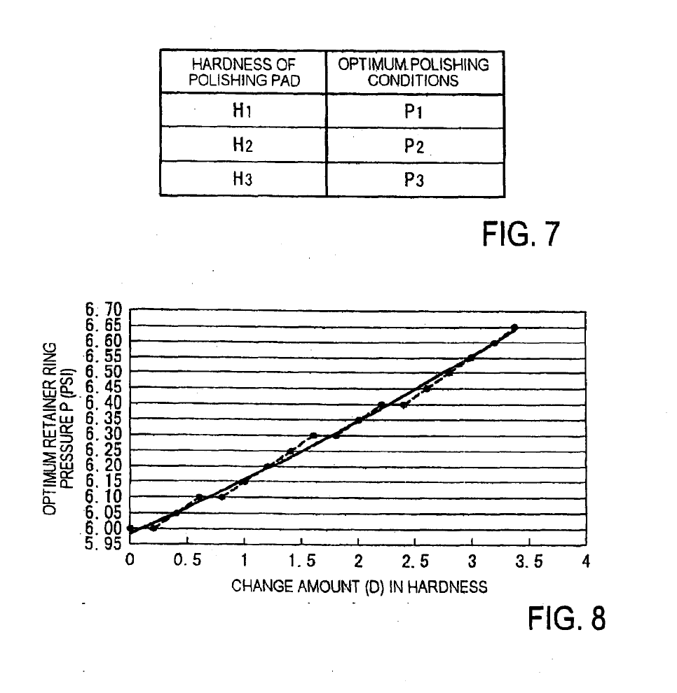

FIG. 7 gives a schematic representation of data stored in storage unit 13. A correspondence relation between hardness (H) of a polishing pad and optimum polishing conditions (P) for uniformly polishing a surface is stored in storage unit 13. This correspondence relation is obtained by, for example, carrying out hardness measurements together with the number of wafers processed and then investigating the conditions in which the surface of semiconductor wafer 19 was most uniformly polished for each hardness.

The pressure applied to retainer ring 10 and the pressure applied to membrane 18c for adjusting pressure fluctuation at the peripheral portion of a semiconductor wafer are preferably selected as the polishing conditions (P). The distribution of pressure at the edges of semiconductor wafer 19 largely depends on the balance between the pressure of retainer ring 10 and the pressure applied to the outer periphery of the semiconductor wafer.

The correspondence relation stored in storage unit 13 may be represented by an approximation formula rather than by a table such as shown in FIG. 7. Further, the correspondence relation may be described between polishing conditions (P) and the amount of change (D) from the initial hardness (the hardness when unused), rather than using the actual current hardness. When using the correspondence relation between the amount of change (D) and the polishing conditions (P), a numerical value of the initial hardness of the polishing pad is stored in the storage unit.

As one example of the use of the amount of change (D), FIG. 8 is a graph showing the relation between the amount of change (D) from the initial hardness of polishing pad 20 and the optimum retainer ring pressure. In the example shown in FIG. 8, the relation between polishing conditions P (optimum retainer ring pressure) and hardness information (amount of change D from the initial hardness) can be represented by an approximation formula by carrying out polynomial approximation. In this case, an approximation formula in which quadratic approximation is carried out may be stored in storage unit 13. An example of the approximation formula is:

P=0.0081D²+0.1653D+5.986.

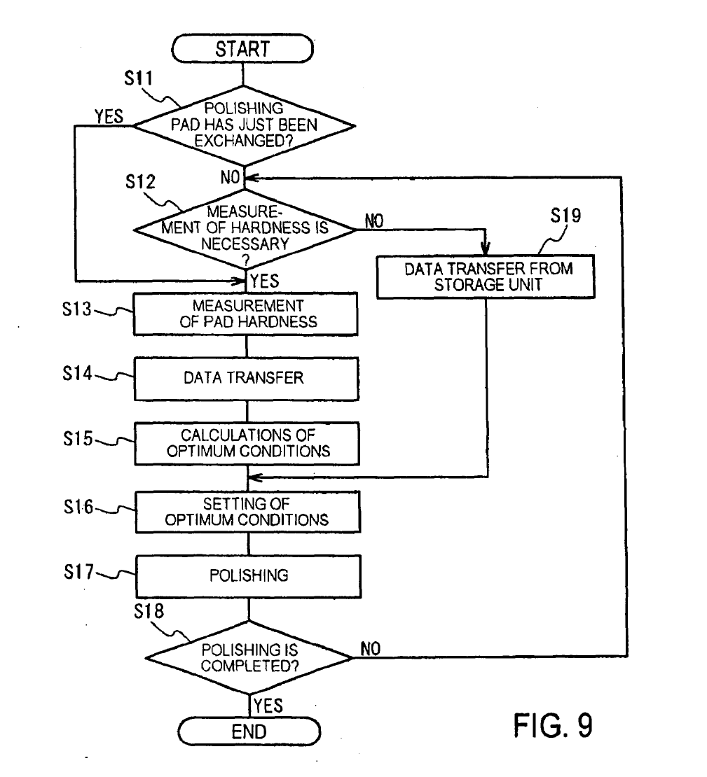

Explanation next regards the semiconductor device fabrication method according to the first embodiment. The method described hereinbelow is realized by control unit 11. FIG. 9 is a flow chart of the fabrication method in the first embodiment. Explanation next regards the details of each step.

Step S11 [Determining Whether Polishing Pad has Just been Exchanged]:

When the start of a polishing process has been instructed, control unit 11 first determines, in Step S11, whether polishing pad 20 has just been exchanged. When polishing pad 20 has just been exchanged, a measurement of the pad hardness is executed in Step S13. If the polishing pad has not just been exchanged, a determination of whether to measure hardness is executed in Step S12.

Step S12 [Determining Whether to Execute Measurement of Hardness]:

When it is determined in Step S11 that the polishing pad has not just been exchanged, it is next determined whether to execute a measurement of hardness in Step S12. Standards that can be used for this determination include the number of processed semiconductor wafers 19 and the time interval which polishing pad 20 has been left on. In other words, control unit 11 determines a hardness measurement should be carried out after a prescribed number of wafers have been processed, or when polishing pad 20 has been left on over the passage of at least a prescribed time interval. If it is determined that a hardness measurement must be executed, the process proceeds to the succeeding Step S13. On the other hand, if it is determined that a hardness measurement need not be executed, polishing condition data of the same conditions as during the preceding polishing are transferred from storage unit 13 in Step S19 and these polishing conditions then set in Step S16.

Steps S13 and S14 [Measuring Hardness of Polishing Pad]:

When control unit 11 had determined in Step S12 that a hardness measurement must be carried out, a measurement of the hardness of polishing pad 20 is carried out by means of hardness meter 7 in Step S13. The data obtained by the measurement of hardness meter 7 is then transferred to control unit 1 in Step S14. In the case of a measurement immediately following exchange of polishing pad 20, the data obtained in the measurements of Steps S13 and S14 are stored as necessary in storage unit 13 as the initial hardness.

Step S15 [Calculating Optimum Polishing Conditions]:

When hardness data have been transferred from hardness meter 7 to control unit 11 in Step S14, calculation unit 14 calculates the optimum polishing conditions in Step S15. More specifically, calculation unit 14 refers to storage unit 13 and, based on the correspondence relation between the hardness data and the optimum polishing conditions described in storage unit 13, obtains the optimum polishing conditions corresponding to the hardness data which have been measured. As previously described, examples of the optimum polishing conditions found here include the pressure of retainer ring 10 and the pressure of membrane 18a.

When the data described in storage unit 13 are a correspondence relation between the amount of change D from the initial hardness and the optimum polishing conditions, the amount of change D of hardness is calculated from the hardness data measured in the process of Step S13 and the initial hardness stored in storage unit 13. Control unit 11 then obtains the optimum polishing conditions corresponding to the amount of change D that has been calculated.

Steps S16 and S17 [Setting Optimum Conditions and Polishing]:

Control unit 11 next sets, in Step S16, the optimum polishing conditions that have been obtained as the polishing conditions. When it is determined in the process of Step S12 not to execute a hardness measurement, the polishing conditions at the time of the preceding polishing process are set without change in Step S16. Control unit 11 then effects control of the operation of polishing unit 12 in Step S17 such that semiconductor wafer 19 is polished under the polishing conditions that have been set. Upon completion of one semiconductor wafer 19, head 1 and polishing pad 20 are cleaned with pure water. The cleaning equipment used in this cleaning is omitted from the figure. Next; control unit 11 determines whether there is further semiconductor wafer to be polished in Step S18. When polishing the next semiconductor wafer, the process returns from Step S18 to the process of Step S12 and the processes of Steps S13 to S19 are repeated, otherwise the fabrication process is completed.

According to the first embodiment, the optimum polishing conditions are found based on the hardness of polishing pad 20, whereby the tendency for non-uniformity of pressure that occurs at the edges of semiconductor wafer 19 can be constantly suppressed and the surface of semiconductor wafer 19 can be uniformly polished.

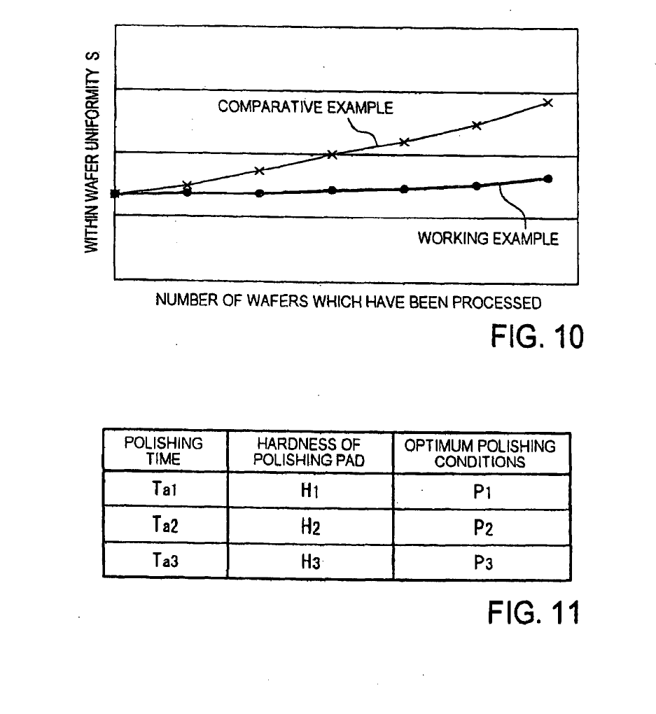

FIG. 10 is a graph for explaining the effects of the first embodiment, the horizontal axis showing the number of wafers processed and the vertical axis showing the within wafer uniformity S of the polishing amount. The within wafer uniformity S is represented by a value which is obtained by dividing the difference between the maximum polishing amount pₘₐₓ and the minimum polishing amount pₘᵢₙ in the processed semiconductor wafers by the twice of the average polishing amount pₐᵥ. That is, S=(pₘₐₓ−pₘᵢₙ)/(2 pₐᵥ). The comparative example is a case in which polishing was carried out with fixed polishing conditions regardless of the number of wafers processed. The working example is a case in which the hardness of the polishing pad was constantly measured and the optimum polishing conditions then calculated according to the present invention. In the comparative example, the value for the within wafer uniformity S is deteriorated as the number of processed wafers increased. This effect is seen because the hardness of the polishing pad changes as the number of polishing processes increases. In other words, when the hardness of the polishing pad changes, the reaction force applied toward semiconductor wafer 19 from polishing pad 20 changes at the edges of semiconductor wafer 19. This result arises due to the non-uniformity in pressure that occurs at the edges of semiconductor wafer 19. In contrast, in the present working example, even when a change occurs in the hardness of the polishing pad, the polishing process is executed at the optimum polishing conditions corresponding to the hardness that follows this change, whereby the tendency toward non-uniformity of pressure at the edges of semiconductor wafer 19 is suppressed. As a result, the surface of semiconductor wafer 19 is uniformly polished.

In the first embodiment, the optimum polishing conditions are found based on the hardness of polishing pad 20, but the elastic deformation rate of polishing pad 20 may be used in place of hardness. In this case, an elastic deformation rate measurement device that can measure the elastic deformation rate is used as a constituent element in place of hardness meter 7. In addition, a correspondence relation between the elastic deformation rate and optimum polishing conditions is stored in storage unit 13 in place of the correspondence relation between hardness and the optimum polishing conditions. Despite this use of the elastic deformation rate instead of hardness, the pressure at the edges of a semiconductor wafer can be similarly kept uniform.

### Second Embodiment

Explanation next regards the second embodiment. In the second embodiment, the method of calculating the optimum polishing conditions differs from that of the first embodiment. In other words, the functional configuration of control unit 11 is different.

In contrast to the first embodiment in which the hardness of polishing pad 20 is actually measured and the optimum polishing conditions then found based on the measurement results, in the second embodiment, the hardness of the polishing pad is estimated based on the time interval over which polishing pad 20 is exposed to exhausting conditions and the optimum polishing conditions then found based on this estimated hardness. No hardness meter is therefore necessary in the second embodiment. The configuration of polishing unit 12 is identical to that of the first embodiment, and redundant explanation is therefore omitted. The following explanation regards the functional configuration of control unit 11.

Control unit 11 includes calculation unit 14 and storage unit 13, as in the first embodiment. However, the functions of calculation unit 14 and the data that are stored in storage unit 13 differ from the first embodiment.

Calculation unit 14 realizes the function of finding the optimum polishing conditions based on the accumulated polishing time of the polishing pad that is currently applied to platen 3. At this time, calculation unit 14 refers to storage unit 13 and finds the optimum polishing conditions.

FIG. 11 gives a schematic representation of an example of the data stored in storage unit 13. In storage unit 13, a correspondence relation is described between the accumulation of time over which polishing pad 20 is used in polishing processes, i.e., polishing time (Ta), and hardness (H). As in the first embodiment, the correspondence relation between hardness (H) and the optimum polishing conditions (P) is also described in storage unit 13.

The accumulated polishing time (not shown in the figure) from the exchange of polishing pad 20 is also stored in storage unit 13.

The hardness of polishing pad 20 tends to depend on the polishing time. The correspondence relation between the polishing time (Ta) and hardness (H) can therefore be found in advance by measuring the hardness of the polishing pad at various polishing times.

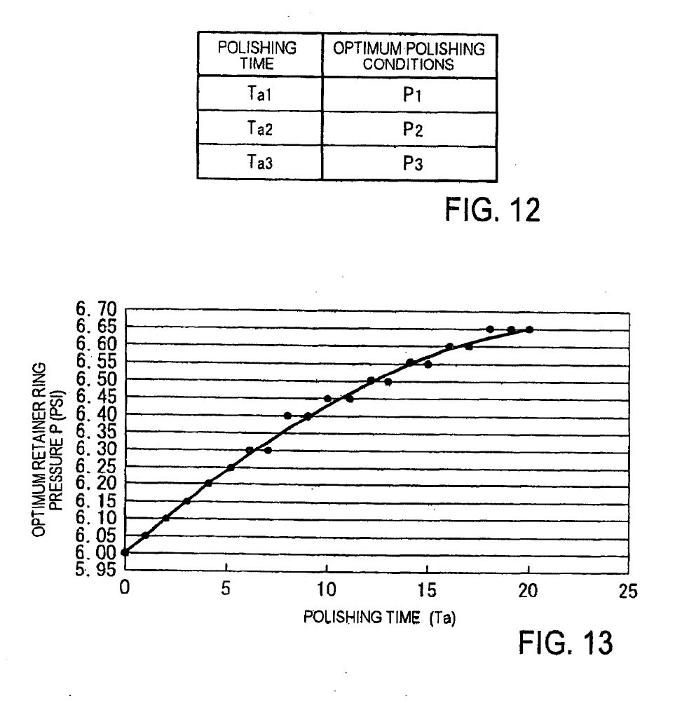

In each of the above-described correspondence relations, hardness (H) may be omitted and the optimum polishing conditions (P) placed in direct correspondence with the polishing time (Ta). FIG. 12 gives a schematic representation of another example of the data stored in storage unit 13 when the optimum polishing conditions (P) and the polishing time (Ta) are placed in direct correspondence. Because the optimum polishing conditions (P) depend on hardness (H) and hardness (H) depends on the polishing time (Ta), the optimum polishing conditions (P) can be placed in direct correspondence with the polishing time (Ta). By taking this approach, the composition of the data stored in storage unit 13 can be simplified, whereby the hardware composition of storage unit 13 can be simplified.

FIG. 13 is a graph showing an example of the correspondence relation between polishing time (Ta) and the optimum polishing conditions (P). The retainer ring pressure is used as the optimum polishing condition (P). In the example shown in FIG. 13, through the use of polynomial approximation, the optimum retainer ring pressure P can be represented by the approximation formula:

P(PSI)=−0.0011Ta²+0.054Ta+6.0007

### When the correspondence relation can be represented by an approximation formula in this way, only this approximation formula need be stored in storage unit 13.

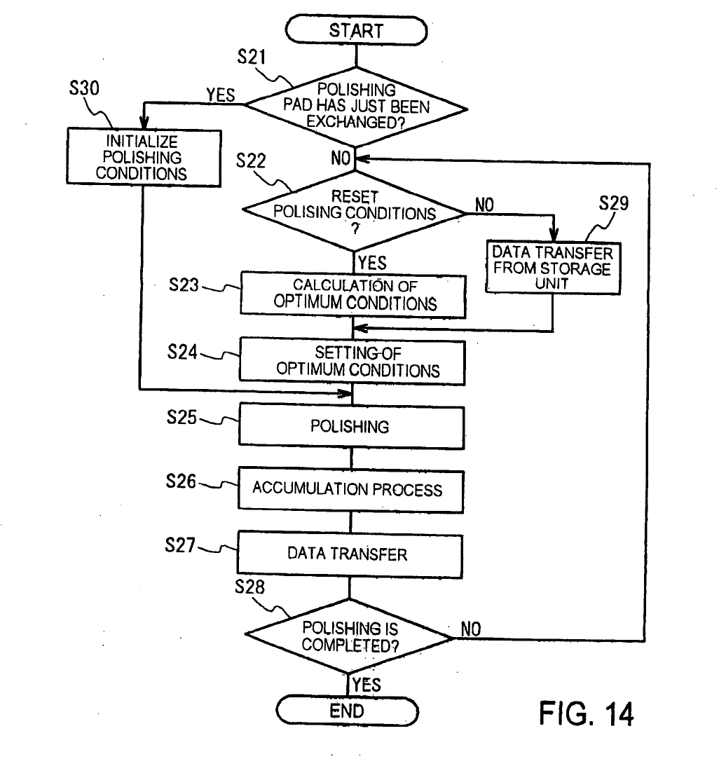

Explanation next regards the details of each step of the semiconductor device fabrication method according to the second embodiment. FIG. 14 is a flow chart of the fabrication method in the second embodiment.

Step S21 [Determining Whether Polishing Pad has Just been Exchanged]:

As in the first embodiment, it is first determined whether the polishing pad has just been exchanged in Step S21. When the polishing pad has just been exchanged, the polishing conditions are initialized in Step S30, and polishing of semiconductor wafer 19 is carried out in Step S25 under the conditions of the initial setting which is the optimum polishing conditions corresponding to polishing time Ta=0. On the other hand, if the polishing pad has not been exchanged immediately beforehand, the process proceeds to the succeeding Step S22.

Step S22: [Determining Whether Polishing Conditions Must be Reset]:

If the polishing pad has not been just exchanged in Step S21, it is next determined whether the polishing conditions must be reset in Step S22. Standards that can be used as a basis for this determination include, for example, the number of semiconductor wafers 19 that have been processed and the time interval that polishing pad 20 has been left on. In other words, control unit 11 determines to reset the polishing conditions after processing a prescribed number of wafers, or when the time interval that polishing pad 20 has been left on equals or surpasses a prescribed time interval. If it is determined that the polishing conditions must be reset, the procedure advances to the succeeding Step S23. On the other hand, if it is determined that resetting is not necessary, polishing condition data identical to the preceding polishing are transferred from storage unit 13 to control unit 11 in Step S29 and these polishing conditions are set in control unit 11 in Step S24.

Steps S23 and S24 [Calculating Optimum Conditions]:

If it is determined in Step S22 that the polishing conditions are to be reset, calculation unit 14 obtains the accumulated polishing time that is stored in storage unit 13. Calculation unit 14 then refers to the correspondence relation between the polishing time (Ta) and hardness (H) which is stored in storage unit 13 to estimate the current hardness of polishing pad 20. Calculation unit 14 further refers to the correspondence relation between hardness (H) and optimum polishing conditions (P) to find the optimum polishing conditions (P) that correspond to the estimated hardness in Step S23. The optimum polishing conditions (P) that have been thus found are set as the polishing conditions in Step S24.

Steps S25, S26, and S27 [Polishing and Accumulation Processes]:

Control unit 11 controls the operations of polishing unit 12 in Step S25 such that semiconductor wafer 19 is polished in accordance with the polishing conditions that have been set. Upon completion of polishing, control unit 11 accumulates the time required for polishing in Step S26. Control unit 11 then transfers the accumulated polishing time data to storage unit 13 in Step S27 and rewrites the accumulated polishing time.

After Step S27, control unit 11 determines whether there is further semiconductor wafer to be polished in Step S28. The processes of the above described Steps S21 to S27 are repeated with each semiconductor wafer 19 polished. If no unprocessed semiconductor wafer remains in Step S28, the fabrication process is completed.

According to the second embodiment, the step of measuring hardness is omitted from the first embodiment, whereby an improvement of throughput in the polishing processes of semiconductor wafer 19 can be achieved in addition to obtaining the same advantageous effect as the first embodiment.

### Third Embodiment

Explanation next regards the third embodiment. The third embodiment provides an additional modification of the functional configuration of control unit 11 compared to the second embodiment. In the second embodiment, the optimum polishing conditions were found from the accumulation of time over which polishing pad 20 is used in the polishing process, but in the third embodiment the optimum polishing conditions are found based on the time interval over which polishing pad 20 is placed in wet idle in addition to the accumulated time of the polishing process. Regarding points other than the functional configuration of control unit 11, the third embodiment is identical to the second embodiment and redundant explanation of these points is therefore omitted.

As in the second embodiment, control unit 11 includes storage unit 13 and calculation unit 14. Calculation unit 14 realizes the functions of referring to storage unit 13 to find the optimum polishing conditions (P) and taking these polishing conditions as the setting conditions.

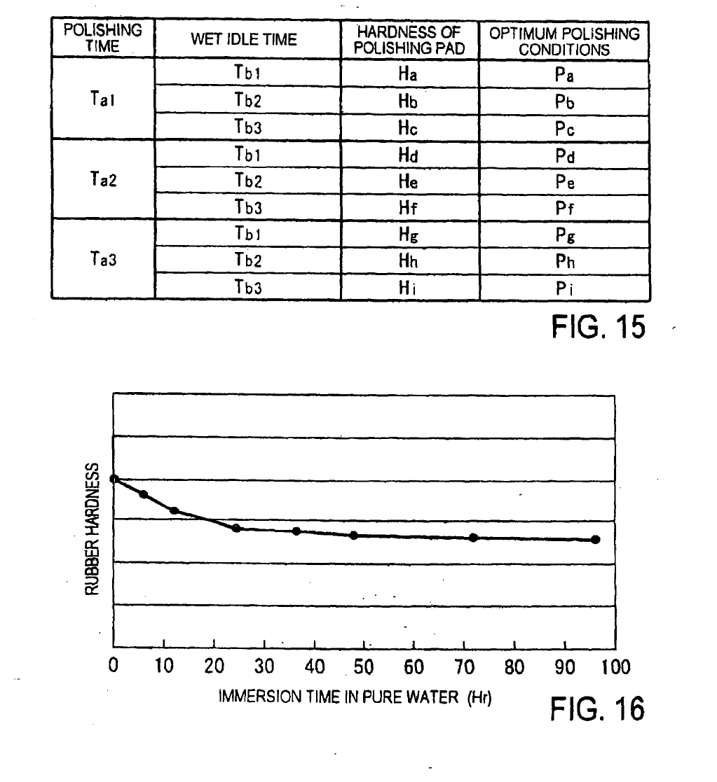

FIG. 15 gives a schematic representation of an example of the data stored in storage unit 13. Data in which the hardness (H) of the polishing pad is placed in correspondence with the polishing time (Ta) and the wet idle time (Tb) are stored in storage unit 13. The correspondence relation between the hardness (H) of the polishing pad and the optimum polishing conditions (P) is also stored in storage unit 13. The correspondence relation of hardness (H) with the polishing time (Ta) and wet idle time (Tb) can be found in advance by measuring the hardness for each wet idle time of each polishing time. Storage unit 13 further stores the accumulated wet idle time (not shown in the figure) and the accumulated polishing time (not shown in the figure) of polishing pad 20 which is currently applied to platen 3.

Here, wet idle time (Tb) indicates the accumulation of time over which polishing pad 20 is placed in wet idle. Upon completion of polishing of one semiconductor wafer 19, polishing pad 20 is cleaned with pure water, and at this time, polishing pad 20 is placed in wet idle. Depending on the type of polishing pad 20, placement in the wet idle changes the hardness of the polishing pad. FIG. 16 is a graph showing the change in hardness when a polishing pad made of polyurethane is soaked in pure water and thus placed in wet idle. The example of FIG. 16 shows when the polishing pad is soaked in pure water over a long time interval, its hardness drops.

When the correspondence relation of hardness (H) with the polishing time (Ta) and wet idle time (Tb) can be expressed as an approximation formula, this approximation formula may be stored in storage unit 13. For example, an approximation formula indicating the correspondence relation between the wet idle time and hardness for each polishing time may be stored.

In the semiconductor device fabrication method according to the third embodiment, the operation in the step for calculating the optimum conditions in Step S23 (see, FIG. 14) is more involved than in the second embodiment. In Step S23, control unit 11 first obtains from storage unit 13 the stored or accumulated polishing time data and wet idle time data. Control unit 11 further estimates the current hardness of polishing pad 20 based on the correspondence relation between the hardness (H) and the polishing time (Ta) and wet idle time (Tb) which are stored in storage unit 13. Control unit 11 then refers to the correspondence relation between hardness (H) and optimum polishing conditions (P) which is stored in storage unit 13 to obtain the optimum polishing conditions (P). The subsequent operations are identical to operations in the second embodiment.

As described in the foregoing explanation, hardness is estimated in the third embodiment by taking into consideration not only the time interval over which polishing pad 20 is used in polishing but also the wet idle time over which polishing pad is placed in wet idle, whereby hardness can be more accurately estimated when using polishing pad 20 in which hardness changes when exposed to damp conditions.

Although explanation in the third embodiment regarded a case in which two correspondence relations (i.e., the correspondence relation of the hardness with the polishing time and dampness exposure time, and the correspondence relation between the hardness and the optimum polishing conditions) were stored in storage unit 13, the optimum polishing conditions may also be placed in direct correspondence with the polishing time and wet idle time. Adopting this approach allows a simplification of the composition of data stored in storage unit 13 and therefore enables a simplification of the hardware composition of storage unit 13.

The first to third embodiment explained hereinabove can be used in combination to the extent that does not result in contradictions.

Although the preferred embodiments of the present invention have been described in detail, it should be understood that various changes substitutions and alternations can be made therein without departing from spirit and scope of the inventions as defined by the appended claims.

What is claimed is:

1. A method of fabricating a semiconductor device whereby a semiconductor wafer is polished by pressing the semiconductor wafer against a polishing pad, said method comprising:
an optimum condition calculation step for finding polishing conditions based on hardness of said polishing pad; and
a step of polishing said semiconductor wafer according to the polishing conditions that have been found.

2. The method according to claim 1, further comprising: a step of measuring the hardness of said polishing pad,
wherein, in said optimum condition calculation step, said polishing conditions are found based on the measured hardness of said polishing pad.

3. The method according to claim 1, wherein:
said optimum condition calculation step includes a step for estimating the hardness of said polishing pad based on time information that indicates a time interval over which said polishing pad has been exposed to conditions causing exhaustion; and
said polishing conditions are found based on the estimated hardness of said polishing pad.

4. The method according to claim 3, wherein said time information includes polishing time that indicates a time interval over which said polishing pad has been used in polishing process.

5. The method according to claim 3, wherein said time information includes wet idle time indicating a time interval over which said polishing pad is placed in wet idle.

6. The method according to claim 1, wherein said polishing conditions include retainer ring pressure at which a retainer ring, which is arranged around a periphery of a semiconductor wafer during polishing and which guides the semiconductor wafer, is pressed against said polishing pad.

7. The method according to claim 1, wherein said polishing conditions include a peripheral pressure that is applied to an outer periphery of said semiconductor wafer when said semiconductor wafer is pressed against said polishing pad.

8. A method of fabricating a semiconductor device whereby a semiconductor wafer is polished by pressing the semiconductor wafer against a polishing pad; said method comprising:
an optimum condition calculation step for finding polishing conditions based on elastic deformation rate of said polishing pad; and
a step of polishing said semiconductor wafer according to the polishing conditions that have been found.

9. A method of fabricating a semiconductor device whereby a semiconductor wafer is polished by pressing the semiconductor wafer against a polishing pad, said method comprising:
an optimum condition calculation step for finding polishing conditions based on time information indicating a time interval over which said polishing pad is exposed to conditions causing exhaustion; and
a step of polishing according to polishing conditions that have been found.

10. A device for fabricating a semiconductor device wherein a semiconductor wafer is polished by pressing the semiconductor wafer against a polishing pad, said device comprising:
a polishing unit that includes a polishing pad for polishing said semiconductor wafer; and
a control unit for finding polishing conditions based on hardness of said polishing pad and controlling operation of said polishing unit such that polishing is carried out under the polishing conditions that have been found.

11. The device according to claim 10, further comprising a hardness measurement unit for measuring the hardness of said polishing pad, wherein said control unit finds said polishing conditions based on the measurement results of said hardness measurement unit.

12. The device according to claim 10, wherein said control unit estimates the hardness of said polishing pad based on time information that indicates a time interval over which said polishing pad is exposed to conditions that cause exhaustion, and finds said polishing conditions based on the hardness of said polishing pad that has been estimated.

13. The device according to claim 12, wherein said time information includes polishing time that indicates a time interval over which said polishing pad has been used in the polishing process.

14. The device according to claim 12, wherein said time information includes wet idle time that indicates a time interval over which said polishing pad is place in wet idle.

15. The device according to claim 10, wherein said polishing conditions include retainer ring pressure at which a retainer ring, which is arranged around a periphery of a semiconductor wafer during polishing and which guides the semiconductor wafer, is pressed against said polishing pad.

16. The device according to claim 10, wherein said polishing conditions include a peripheral pressure that is applied to an outer periphery of said semiconductor wafer when said semiconductor wafer is pressed against said polishing pad.

17. A device for fabricating a semiconductor device wherein a semiconductor wafer is polished by pressing the semiconductor wafer against a polishing pad, comprising:
a polishing unit that includes a polishing pad for polishing said semiconductor wafer; and
a control unit for finding polishing conditions based on elastic deformation rate of said polishing pad, and controlling operation of said polishing unit such that polishing is carried out according to the polishing conditions that have been found.

18. A device for fabricating a semiconductor device wherein a semiconductor wafer is polished by pressing the semiconductor wafer against a polishing pad, comprising:
a polishing unit that includes a polishing pad for polishing said semiconductor wafer; and
a control unit for finding polishing conditions based on time information that indicates a time interval over which said polishing pad is exposed to conditions causing exhaustion, and controlling operation of said polishing unit such that polishing is carried out by the polishing conditions that have been found.
